(19) United States
(12) Patent Application Publication
(10) Pub. No.: US 2009/0127701 A1
(43) Pub. Date: May 21, 2009

(54) Thermal attach for electronic device cooling

(76) Inventors: Nitin Goel, Bangalore (IN); Anandaroop Bhattacharya, Bangalore (IN); Rajiv Mongia, Fremont, CA (US)

Correspondence Address: Kirton & McConkie Attorneys at Law, c/o Intellevate, LLC, P.O. Box 52050, Minneapolis, MN, 55402, US

(21) Appl. No.: 11/985,583

(22) Filed: Nov. 15, 2007

(51) Int. Cl. H01L 23/36

(52) U.S. Cl. 257/713; 257/E23.101

(57) ABSTRACT

Embodiments of thermal cooling devices and systems including dies and thermal attaches having surface features are described in this application. The thermal attach may have a surface feature, such as a pattern, to limit movement of a thermal interface material, such as thermal grease, from between the die and the thermal attachment. The restriction of movement of the thermal interface material may improve the thermal performance of cooling systems for electronic devices over many cycles as opposed to known cooling systems. Other embodiments are described.

### FIELD

This application relates generally to heat dissipation in electronic devices. In particular, this application relates to improved heat dissipation in laptop computers by preventing heat pump-out of thermal interface materials (“TIM's”).

### BACKGROUND

Keeping laptops cool is a major design challenge as laptops become slimmer and smaller. In addition, laptop owners use laptops in a variety of environments and expect their laptops to continually perform. Integrated circuit dies are usually composed of dissimilar material such as silicon chip interconnected on a package substrate through epoxy under-fill. A significant amount of coefficient of thermal expansion (“CTE”) mismatch exists between these materials. The mismatch leads to the surface warping of the die during heat cycling as a result, a flexing and shearing motion between the die and the thermal attachment results in pump out of the TIM. One existing problem with the use of smooth thermal attachment mating surface on a warped die surface is that the TIM may be heated and pumped out of the space between the die and the thermal attachment due to changes in dimension and surface shape of one or both of the mating surfaces, and due to heat-related lower viscosity of the TIM. The cyclical temperature changes cause the thickness of the TIM to change, forcing more and more of the TIM out of the space between the die and thermal attachment during each cycle, thereby reducing the thermal transfer performance of laptop's cooling system. At some point, the laptop may fail, either temporarily or permanently, due to high heat in the laptop's electronic components. Laptop computers usually have more cyclic load because of the mobile and various uses employed by laptop users, thereby reducing the life of the computer.

### BRIEF DESCRIPTION OF THE DRAWINGS

The following description can be better understood in light of Figures, in which:

FIG. 1 illustrates a perspective view of a conventional cooling system;

FIG. 2A illustrates a top view of a conventional thermal attachment;

FIG. 2B illustrates a top view of an exemplary embodiment of a thermal attachment;

FIG. 2C illustrates a top view of an exemplary embodiment of a thermal attachment;

FIG. 2D illustrates a top view of an exemplary embodiment of a thermal attachment;

FIGS. 3A and 3B illustrate side views of an exemplary cooling system;

FIG. 4A illustrates the effects of heat cycling on a conventional cooling system;

FIG. 4B illustrates the effects of heat cycling on an exemplary cooling system; and

FIG. 5 is a graph illustrating the performance differences between a conventional cooling system and an exemplary cooling system.

Together with the following description, the Figures demonstrate and explain the principles of the apparatus and methods described herein. In the Figures, the thickness and configuration of components may be exaggerated for clarity. The same reference numerals in different Figures represent the same component.

### DETAILED DESCRIPTION

The following description supplies specific details in order to provide a thorough understanding. Nevertheless, the skilled artisan would understand that the apparatus and associated methods of using the apparatus can be implemented and used without employing these specific details. Indeed, the apparatus and associated methods can be placed into practice by modifying the illustrated apparatus and associated methods and can be used in conjunction with any apparatus and techniques conventionally used in the industry. For example, while the description below focuses on laptop cooling systems, the apparatus and associated methods can be equally applied in other electronic cooling systems. Indeed, the apparatus and associated methods may be implemented in many other cooling applications such as desktop computers, televisions, mobile video players, mobile audio devices, or any other electronic device.

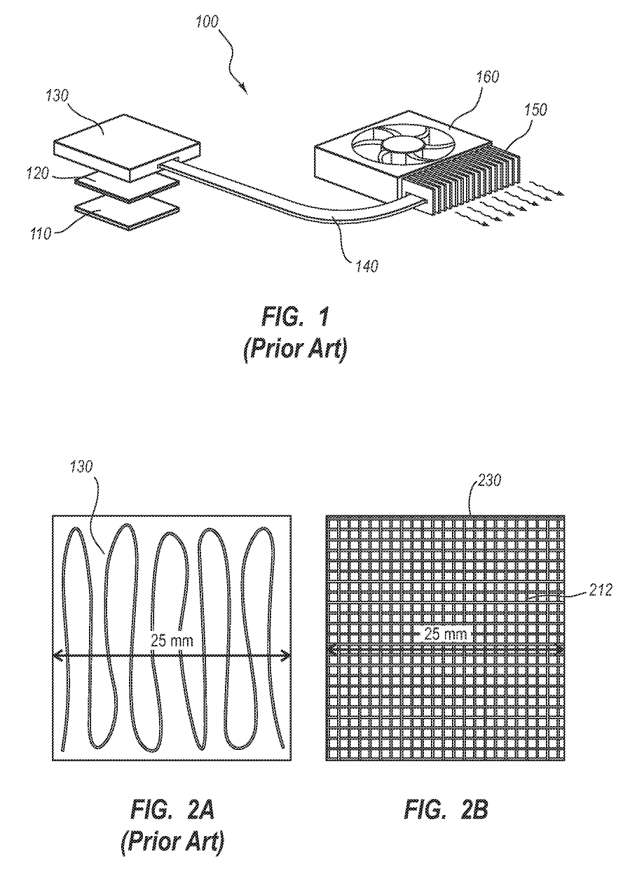

FIG. 1 illustrates a conventional cooling system 100 to allow for slim case design in a laptop computer including heat generating die 110 such as a CPU, graphics and memory controller hub (“GMCH”) or other microprocessor, memory, video chips, etc., and transmits the heat to thermal attachment 130. Thermal attachment 130 then transfers the heat through heat pipe 140 to a remote heat exchanger or heat sink 150, often including a fan 160, for expelling heat from the laptop case.

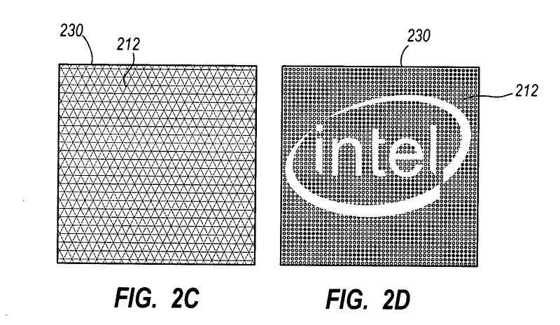

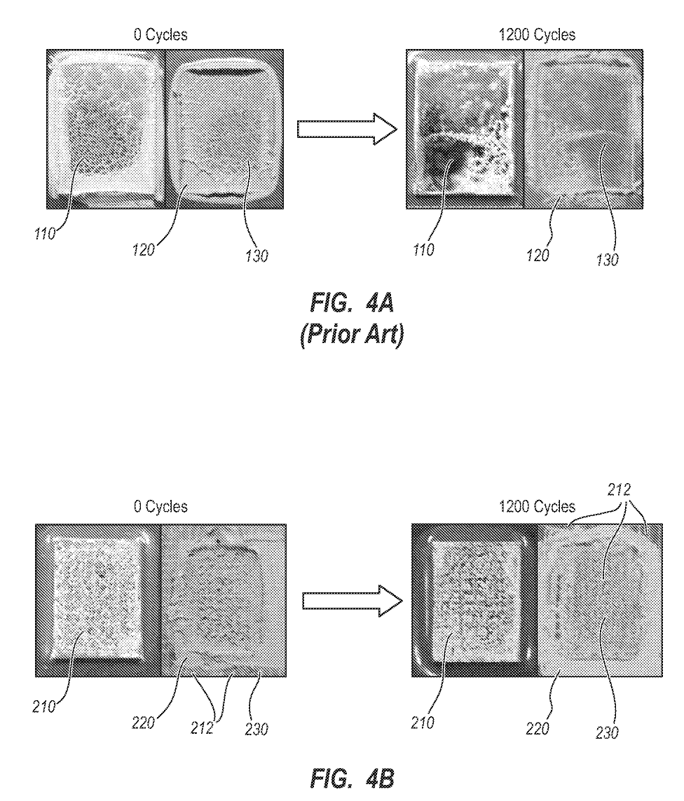

A layer of thermal interface material (“TIM”) 120, such as thermal grease, may be applied between contact surfaces of die 110 and thermal attachment 130 to facilitate heat transfer between die 110 and thermal attachment 130 by reducing the interfacial thermal resistance between die 110 and thermal attachment 130 surfaces. Conventionally, the mating surface of thermal attachment 130 is smooth, (<10 microns), as shown in FIG. 2A. FIGS. 2A and 4A illustrate the surfaces of known die 110 and thermal attachment 130 components.

Die 110 is usually composed of dissimilar material such as silicon chip interconnected on a package substrate through epoxy under-fill. A significant amount of coefficient of thermal expansion (“CTE”) mismatch exists between these materials. The mismatch leads to the surface warping of die 110 during heat cycling as a result, a shearing motion between die 110 and thermal attachment 130 results in pump out of the TIM. One existing problem with the use of smooth thermal attachment mating surface on a warped die surface is that the TIM may be heated and pumped out of the space between the die and the thermal attachment due to changes in dimension and surface shape of one or both of the mating surfaces, and due to heat-related lower viscosity of the TIM.

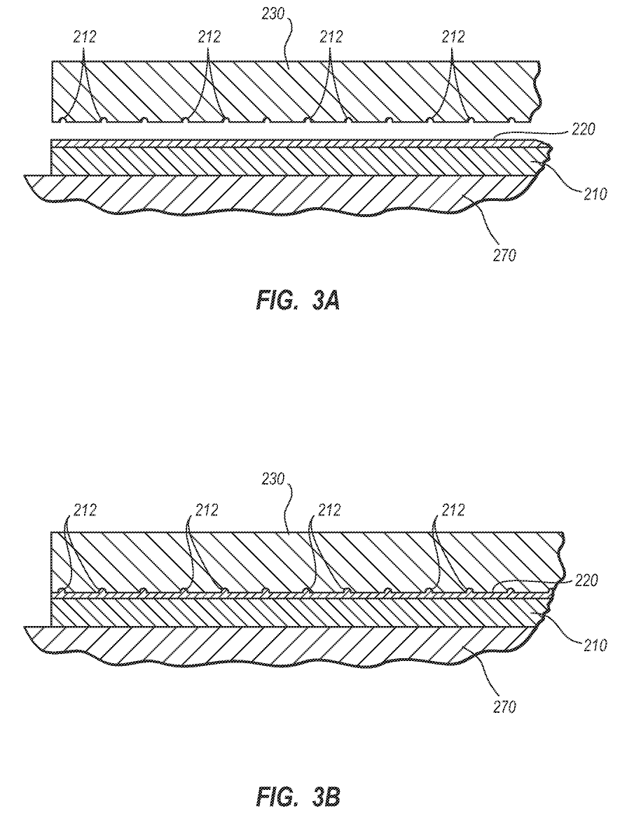

Embodiments of the cooling systems described in this application can have any configuration consistent with its operation described in herein. One exemplary configuration of a die and thermal attachment in a cooling system is illustrated in FIGS. 2B, 3A, 3B, and 4B. FIGS. 2B-2D illustrate embodiments of thermal attachment 230 having surface feature 212, such as a grid pattern, as shown in FIG. 2B, a triangle pattern, as shown in FIG. 2C, and a dimple pattern with a logo, as shown in FIG. 2D. FIGS. 3A and 3B illustrate an embodiment of a grid pattern surface feature 212 on thermal attachment 230 along with die 210, substrate package 270, and TIM 220. TIM 220 may be any known thermal interface material for conducting thermal energy such as thermal grease.

Surface feature 212 may be configured to prevent the flow or movement of TIM 220 away from the interface between thermal attachment 230 and die 210, as illustrated in FIG. 3B. As die 210 heats up when on and working, heat is transferred from die 210 to thermal attachment 230 through TIM 220. Because thermal attachment 230 has better thermal conductive performance than TIM 220, the height of surface features 212 may be optimized to limit migration of TIM 220 while allowing minimal thickness of TIM 220 for increased thermal cooling performance of the entire system.

Thermal attachment 230 may be made of a conductive metal to efficiently conduct heat and die 210 is usually made of silicon, or a silicon compound due to semiconductor architectural requirements. Because thermal attachment 230 and die 210 may be made of different materials, they may have different thermal expansion rates. Package substrate 270 and die 210 may have a mismatch of CTE which results in warping of the die when heated. Under cyclic heating a cooling, this warping movement occurs repeatedly. Surface feature 212 restricts movement of TIM 220 as a result of the heat expansion of die 210 and thermal attachment 230 by creating physical barriers to pump-out of TIM 220.

Embodiments of surface feature 212 may have any scale that accommodates a die or a thermal attachment. For example, in the embodiment illustrated in FIG. 2B, thermal attachment 230 is 25 mm square and the grid pattern of surface feature 212 has a scale of 1 mm square such that about 25 grid lines of surface feature 212 are present in each direction on thermal attachment 230. In addition to a grid pattern, triangle pattern, and dimple pattern shown in the illustrated embodiments, other embodiments of surface feature 212 may be a variety of patterns or features, such as a honeycomb pattern, diamond pattern, random dashed lines or dots, curvilinear, spiral, etc., such that surface feature 212 restricts movement of TIM 220 as described above. Similarly, surface feature 212 may be raised features or lowered features such that a portion of the surface of thermal attachment 230 is raised or lowered with etching, plating, sand blasting, or other surface altering process.

In some embodiments, surface feature 212 may be located on die 210 instead of thermal attachment 230, and may be monolithic with either thermal attachment 230 or die 210. Additionally, surface feature 212 may be made of a different material than either die 210 or thermal attachment 230, and affixed to one or the other of thermal attachment 230 and die 210 using any known method, such as glue, electroplating, etching, sandblasting, etc. In some embodiments, surface feature 212 may be located on both thermal attachment 230 and die 210 and arranged such that they work cooperatively to prevent migration of TIM 220 as described herein.

FIG. 4A illustrates an empirical example of the pump-out of TIM 120 in an interface between known die 110 and thermal attachment 130. A known cooling system with die 110, TIM 120, and thermal attachment 130 were heat cycled 1200 times in the arrangement as shown in FIG. 1. The designs were subjected to power cycling conditions, where the die power was turned on/off every twenty minutes. The power cycling conditions caused die 10 to cycle between ambient and about 80° C. The amount of TIM 120 in the interface between die 110 and thermal attachment 130 were compared before and after the 1200 cycles. FIG. 4A shows that the amount of TIM 120 is greatly reduced between zero cycles and 1200 cycles, to the extent that at 1200 cycles, almost no TIM 120 remains in large areas of the interface between die 110 and thermal attachment 130.

In contrast, FIG. 4B illustrates an empirical example of the improvement of thermal attachment 230 with surface features 212 in maintaining TIM 220 in the interface between die 210 and thermal attachment 230. The cooling system using die 210, TIM 220, and thermal attachment with surface features 212 were heat cycled 1200 times in the arrangement as shown in FIG. 3B. Surface features 212 in the example are arranged in a grid pattern having 1 mm×1 mm squares and having a height of between 25-50 microns. The amount of TIM 220 in the interface between die 210 and thermal attachment 230 were compared before and after the 1200 cycles. FIG. 4B shown that the amount of TIM 220 was maintained throughout the interface between die 210 and thermal attachment 230, maintaining the thermal performance of the interface and TIM 220.

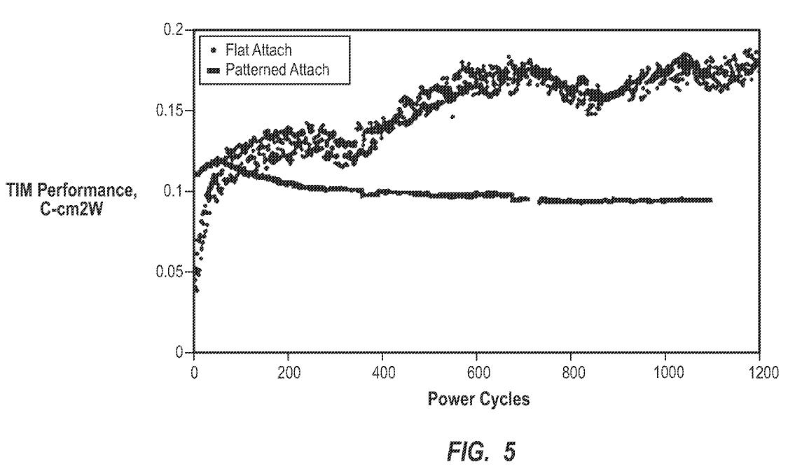

FIG. 5 is a graph illustrating the heat exchange thermal performance for the empirical examples shown in FIGS. 4A and 4B. As shown on the graph, thermal attachment 230 with surface features 212 outperformed known thermal attachment 130 with no surface features over nearly the entire range of cycles. While thermal attachment 130 declined in performance over the length of the experimental 1200 cycles, thermal attachment 230 with surface features 212 improved in performance over the length of the experimental 1200 cycles. In some embodiments, the improved thermal performance may extend beyond the 1200 cycles of the experiment described above.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A heat transfer device, comprising:
a die;
a thermal attachment;
a thermal interface material configured to conduct heat between the die and the thermal attachment; and
a surface feature configured to retain the thermal interface material between the die and the thermal attachment.

2. The device of claim 1, wherein the surface feature is arranged in a pattern.

3. The device of claim 2, wherein the surface feature is located on the thermal attachment.

4. The device of claim 3, wherein the surface feature is integral with the thermal attachment.

5. The device of claim 2, wherein the surface feature is located on the die.

6. The device of claim 2, wherein the pattern is a grid pattern.

7. The device of claim 2, wherein the surface feature contacts each of the thermal interface material, the die, and the thermal attachment.

8. The device of claim 1, wherein the surface feature is of a different material than the thermal attachment.

9. The device of claim 1, wherein the thermal interface material is thermal grease.

10. The device of claim 9, wherein the heat transfer device is configured to be used in a laptop computer.

11. A heat transfer system, comprising:
a substrate, and
a patterned region, the patterned region located on the substrate and including surface features configured to prevent flow of thermal interface material.

12. The system of claim 11, wherein the patterned region is in a grid pattern.

13. The system of claim 11, wherein the heat transfer system is configured to conduct heat away from an integrated circuit, and wherein the substrate is one of the integrated circuit or a thermal attachment.

14. The system of claim 13, wherein the substrate is one of a die configured to be used in a laptop computer, and a thermal attachment.

15. The system of claim 11, wherein the thermal interface material is thermal grease.
